(19) United States
(12) Patent Application Publication
(10) Pub. No.: US 2011/0242777 A1
(43) Pub. Date: Oct. 6, 2011

(54) KEY STRUCTURE AND ELECTRONIC DEVICE EMPLOYING THE SAME

(75) Inventor: RI ZHOU, Shenzhen City (CN)

(73) Assignees: SHENZHEN FUTAIHONG PRECISION INDUSTRY CO., LTD., ShenZhen City (CN); CHI MEI COMMUNICATION SYSTEMS, INC., Tu-Cheng City (TW)

(21) Appl. No.: 12/825,497

(22) Filed: Jun. 29, 2010

(30) Foreign Application Priority Data
Mar. 30, 2010 (CN) 201010136239.3

(51) Int. Cl. H05K 7/02; H01H 9/02

(52) U.S. Cl. 361/760; 200/293

(57) ABSTRACT

A key structure, and an electronic device employing the key structure, includes a housing member and a key body, and the key body is mounted within the housing member for electrically connection to a circuit board. The housing member defines at least one positioning hole; the positioning holes extend through the housing member. The key body includes at least one positioning column. Each at least one positioning column corresponds to a respective positioning hole, and each positioning column is removably received within its corresponding positioning hole to assemble the key body to the housing member.

### BACKGROUND

1. Technical Field

The disclosure generally relates to key structures, and more particularly relates, to a key structure used in an electronic device.

2. Description of the Related Art

Different kinds of keys are generally assembled to circuit boards of mobile phones, personal digital assistants (PDAs), or other electronic devices by surface mount technology (SMT) or other welding method. However, mounting the keys on the circuit board may increase overall thickness of the electronic devices.

In addition, the SMT assembly process is complicated and requires such high processing precision, that even minor errors may result in defective products. Moreover, during the SMT process, the welding materials used may release gases.

Therefore, there is room for improvement within the art.

### BRIEF DESCRIPTION OF THE DRAWINGS

Many aspects of a key structure and an electronic device employing the same can be better understood with reference to the following drawings. The components in the drawings are not necessarily drawn to scale, the emphasis instead being placed upon clearly illustrating the principles of the exemplary key structure and electronic device employing the same. Moreover, in the drawings, like reference numerals designate corresponding parts throughout the several views. Wherever possible, the same reference numbers are used throughout the drawings to refer to the same or like elements of an embodiment.

FIG. 1 is an exploded view of a key structure, according to an exemplary embodiment.

FIG. 2 is similar to FIG. 1 but viewed from the other aspect.

FIG. 3 is an enlarged view of a key body of the key structure shown in FIG. 2.

FIG. 4 is an assembled view of the key structure shown in FIG. 1.

FIG. 5 is an assembled cross-sectional view taken along line V-V of FIG. 4.

FIG. 6 is an assembled cross-sectional view taken along line VI-VI of FIG. 4.

### DETAILED DESCRIPTION

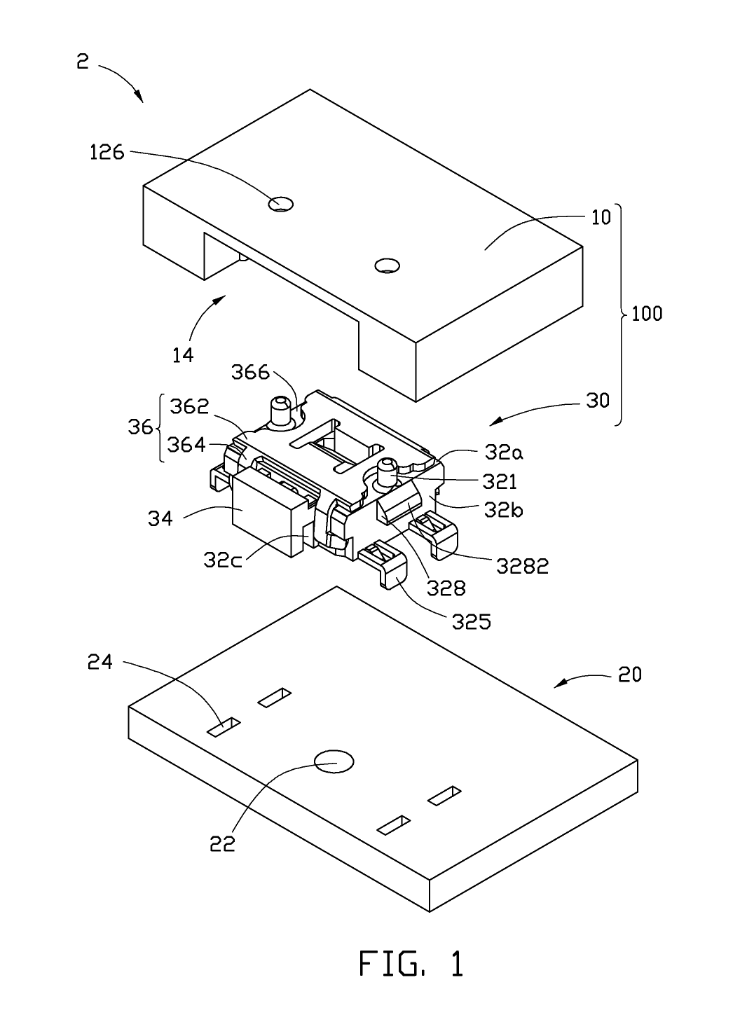

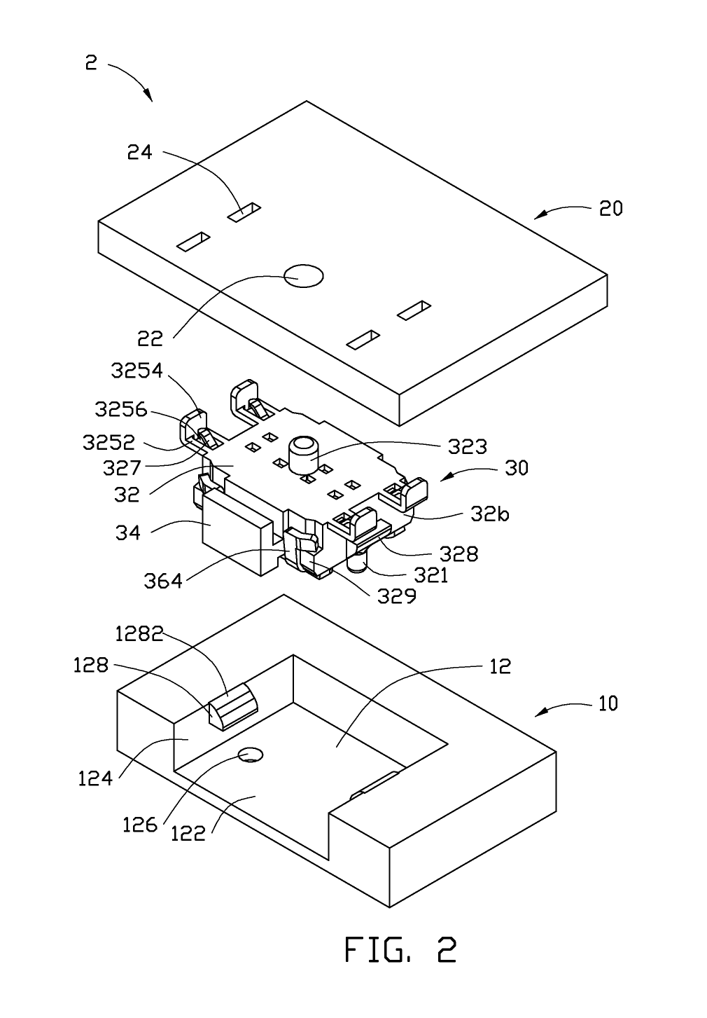

FIGS. 1 and 2 show an exemplary embodiment of a key structure 100 used in an electronic device 2, which may be a mobile phone, or a PDA. The electronic device 2 includes a key structure 100 and a circuit board 20, and the key structure 100 includes a housing member 10 and a key body 30. The key body 30 is mounted between the housing member 10 and the circuit board 20, and is mounted within the housing member 10.

The housing member 10 can be a part of the housing of the electronic device 2 and defines a receiving space 12 and an opening 14 communicating with the receiving space 12. The receiving space 12 is capable of receiving the key body 30. The receiving space 12 includes a bottom surface 122 and side surfaces 124. The bottom surface 122 defines two substantially circular positioning holes 126 that extend through the bottom surface 122.

The side surfaces 124 are perpendicularly connected to the bottom surface 122, and two side surfaces 124 face each other, while the other side surface 124 is perpendicularly connected between the two parallel side surfaces 124. The housing member 10 includes two first locking sections 128 respectively protruding from opposite side surfaces 124. The two first locking sections 128 face each other, and each first locking section 128 includes a mounting surface 1282.

The circuit board 20 can be a printed circuit board (PCB) of the electronic device 2. The circuit board 20 defines a through hole 22 passing through the circuit board 20. The circuit board 20 further defines assembling holes 24 symmetrically arranged at opposite sides of the through hole 22, respectively. The assembling holes 24 pass through the circuit board 20. The circuit board 20 includes a plurality of contacting sections (not shown), and the key body 30 is electrically connected to the circuit board 20 by the contacting sections.

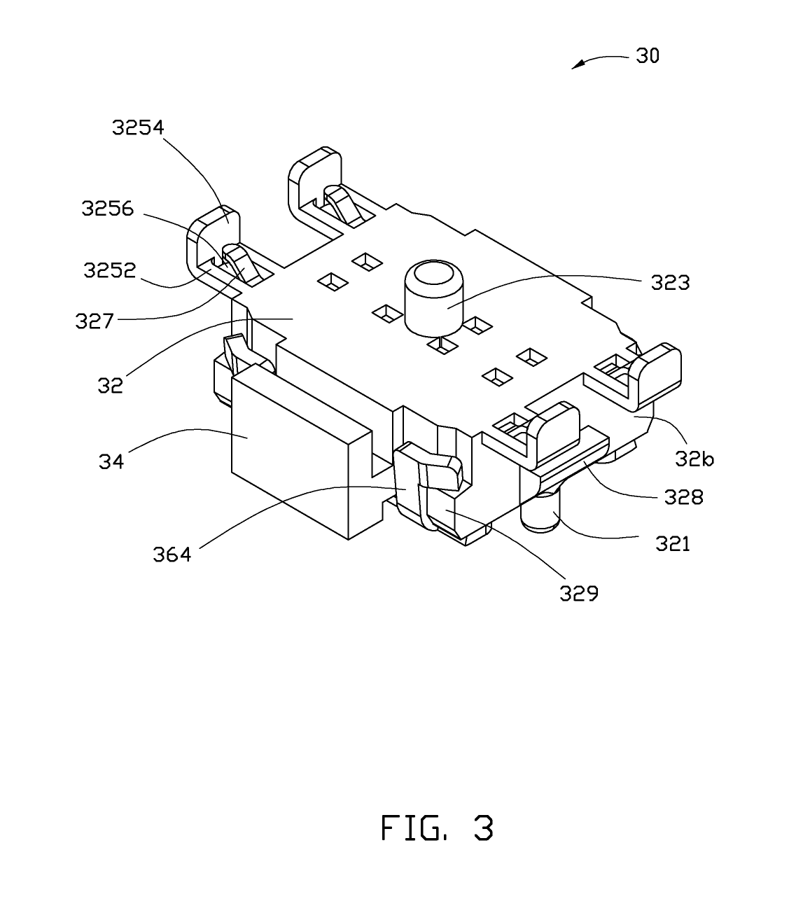

Further referring to FIG. 3, the key body 30 includes a main body 32, an operation body 34, and a frame body 36. The main body 32 is substantially a rectangular block and includes two opposite first surfaces 32a, two opposite second surfaces 32b, and two opposite third surfaces 32c. The main body 32 further includes two positioning columns 321 protruding from one first surface 32a and a fixing column 323 protruding from the other first surface 32a. The shape and the size of the positioning columns 321 substantially match the shape and the size of the positioning holes 126. Thus, the positioning columns 321 can move in and out of the corresponding positioning holes 126 to releasably assemble the key body 30 to the housing member 10. The shape and the size of the fixing column 323 substantially match the shape and the size of the through hole 22 to position the key body 30 on the circuit board 20.

The main body 32 further includes engaging sections 325, conducting sections 327, and two second locking sections 328. The engaging sections 325, the conducting sections 327, and the second locking sections 328 are symmetrically arranged at the two opposite second surfaces 32b. Each engaging section 325 includes a connecting piece 3252 and a fixing piece 3254. The connecting piece 3252 is substantially a rectangular flat sheet and is connected to the second surface 32b, and each connecting piece 3252 defines a matching hole 3256. Each fixing piece 3254 is substantially rectangular sheet and is perpendicularly connected to the distal end of the corresponding connecting piece 3252.

The shape and the size of the fixing pieces 3254 substantially match the shape and size of the assembling holes 24 of the circuit board 20. Thus, the fixing pieces 3245 can move in and out of the corresponding assembling holes 24 to assemble the key body 30 to the circuit board 20 in cooperation with the fixing column 323. The conducting sections 327 may be made from copper, steel, or other metal and formed by punching and/or cutting a piece of metal. An end of the conducting section 327 elastically resists against and electrically connects to an existing switch (not shown); the other end passes through the matching hole 3256 to electrically connect to the circuit board 20. Thus, the key body 30 is electrically connected to the circuit board 20 through the conducting sections 327. The second locking section 328 is made from elastic material and defines a slope 3282. The slope 3282 is located at the distal end of the second locking section 328 and faces the housing member 10.

The main body 32 further includes hinging blocks 329 protruding from the opposite third surfaces 32c, and two hinging blocks 329 are respectively located at opposite sides of each third surface 32c. The operation body 34 is positioned on one of the third surfaces 32c and is located between the two hinging blocks 329. The operation body 34 can reliably move in and out of the main body 32 and is capable of forcing the switch of the main body 32 to turn on and off.

The frame body 36 covers the main body 32 and includes a clasp portion 362 and latching portions 364. The clasp portion 362 is substantially a rectangular sheet and covers one of the first surfaces 32a. The clasp portion 362 defines two notches 366 located at opposite ends of the clasp portion 362. The notches 366 are substantially semicircular and correspond to the positioning blocks 321, so the positioning blocks 321 can be releasably received within and partially exposed from the notches 366. The latching portions 364 are perpendicularly connected to the clasp portion 362 and are capable of clasping the hinging blocks 329 to cooperatively mount the frame body 36 to the main body 32.

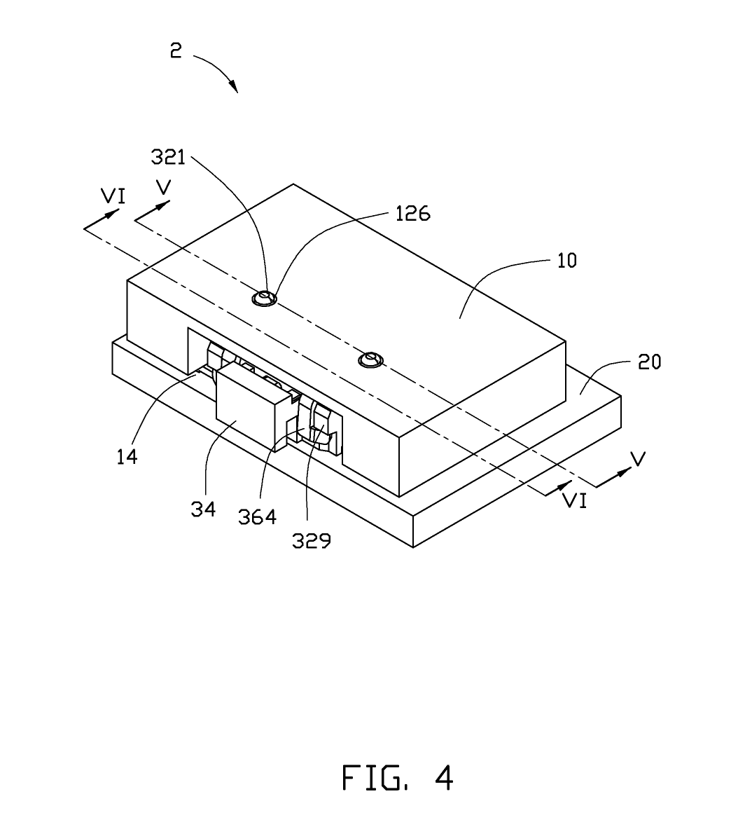

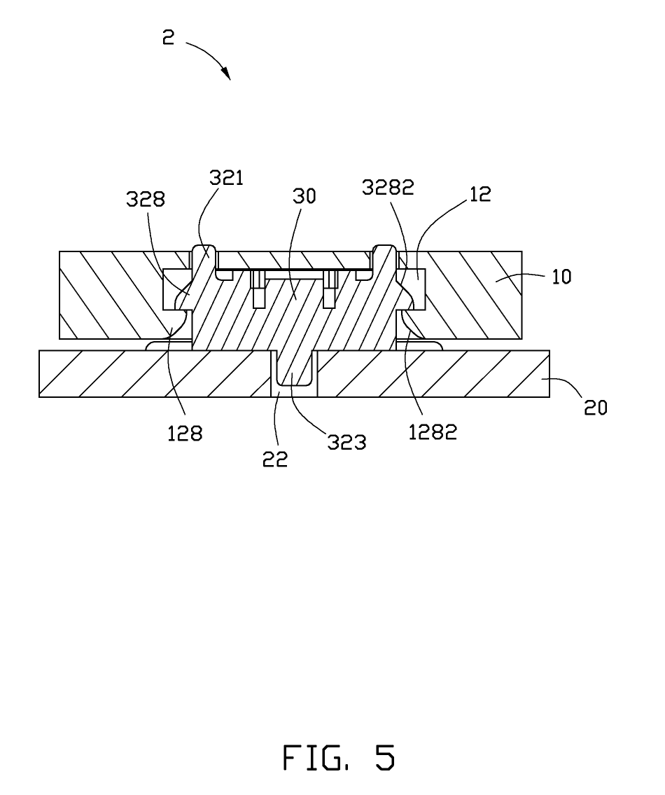

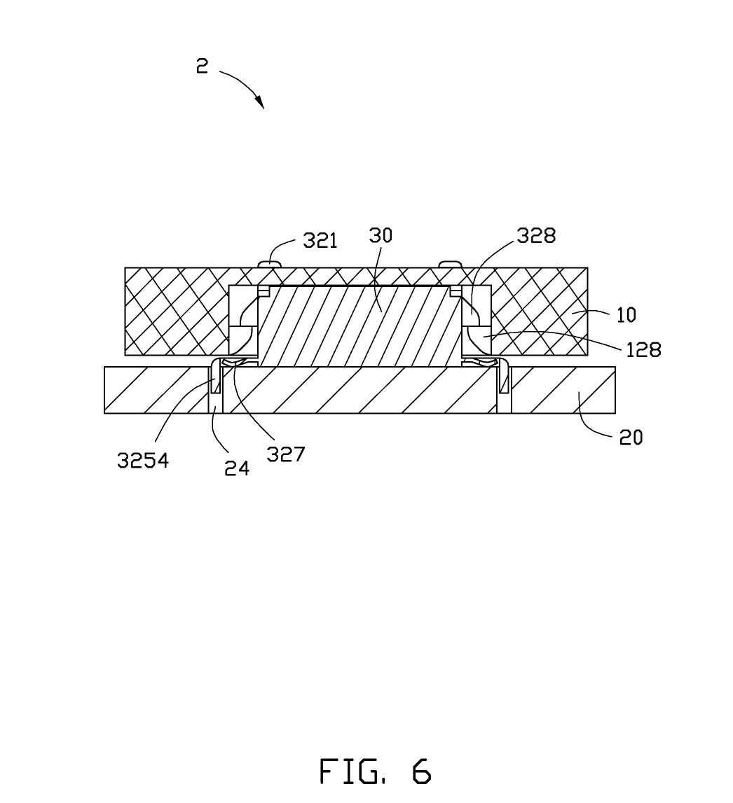

Further referring to FIGS. 4, 5, and 6, in assembly, the fixing column 323 of the main body 32 is aligned with the through hole 22 of the circuit board 20, and the fixing pieces 3254 of the engaging sections 325 are respectively aligned with the corresponding assembling holes 24. The fixing column 323 and the fixing pieces 3254 are detachably mounted into the through hole 22 and the assembling holes 24, respectively, by pressing the main body 32 toward the circuit board 20. Thus, the conducting sections 327 resist against and electrically connect to the circuit board 20 to establish electrical connections. The positioning holes 126 are respectively aligned with the positioning columns 321 of the key body 30, and the first locking sections 128 are aligned with the second locking sections 328. The mounting surfaces 1282 of the first locking sections 128 then slide along the slopes 3282 of the second locking sections 328 by pressing the housing member 10 toward the key body 30. Thus, the second locking sections 328 are removably secured to the first locking sections 328, the operation body 34 is partially exposed from the opening 14, and the key body 30 is mounted between the housing member 10 and the circuit board 20. By operating the operation body 34, the switch of the key body 30 is turned on or off.

In addition, to further miniaturize and simplify the key structure 100, the frame body 36 can be omitted.

In summary, in the key structure 100 and the electronic device 2 employing the same of the exemplary embodiment, the positioning columns 321 are removably mounted in the positioning holes 126 of the housing member 10, and the engaging sections 325 are removably mounted in the corresponding assembling holes 24. Therefore, the key body 30 is mounted between the housing member 10 and the circuit board 20, which allow easy and efficient assembly. Furthermore, the key structure 100 has a simple structure and is easy to manufacture, which can effectively reduce production costs.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A key structure, comprising:
a housing member defining at least one positioning hole, the positioning holes passing through the housing member; and
a key body mounted within the housing member for electrically connection to a circuit board, the key body comprising at least one positioning column, wherein each at least one positioning column corresponds to a respective positioning hole, and each positioning column is removably received within its corresponding positioning hole to assemble the key body to the housing member.

2. The key structure as claimed in claim 1, wherein the key body further comprises a main body and an operation body, each positioning columns are located at the main body.

3. The key structure as claimed in claim 1, wherein the housing member defines a receiving space and an opening communicating with the receiving space, the receiving space capable of receiving the key body, and the operation body is exposed from the opening.

4. The key structure as claimed in claim 3, wherein the receiving space comprises a bottom surface and side surfaces, the positioning holes extend through the bottom surface, the side surfaces are perpendicularly connected to the bottom surface, and two side surfaces face each other, another side surface perpendicularly connecting the facing side surfaces.

5. The key structure as claimed in claim 4, wherein the housing member comprises two first locking sections respectively protruding from opposite side surfaces, the two first locking sections face each other, and each first locking section comprises a mounting surface, wherein the main body further comprises a second locking section located at each opposite surface of the main body, and each second locking section comprises a slope, the mounting surfaces slide along the slopes to mount the first locking section to the second locking section.

6. The key structure as claimed in claim 5, wherein the main body further comprises conducting sections located at opposite surfaces of the main body, an end of the conducting section is electrically connected to the circuit board.

7. The key structure as claimed in claim 2, wherein the key body further comprises a frame body covering the main body, the frame body comprises a clasp portion, the clasp portion defines two notches located at opposite ends of the clasp portion, and the positioning blocks are releasably received within and exposed from the notches.

8. The key structure as claimed in claim 7, wherein the frame body further comprises at least one latching portion connected to the clasp portion, the main body further comprises at least one hinging block protruding from opposite surfaces of the main body, and the latching portions are capable of clasping the hinging blocks to cooperatively mount the frame body to the main body.

9. An electronic device, comprising:
a housing defining a plurality of positioning holes passing through the housing;
a circuit board defining a plurality of assembling holes, and the assembling holes passing through the circuit board; and
a key body mounted between the housing and the circuit board, and electrically connected to the circuit board, wherein the key body comprises a plurality of positioning columns and a plurality of engaging sections, each at least one positioning column and engaging section corresponds to a corresponding positioning holes and a corresponding assembling holes in number, respectively, and each positioning column and each engaging section is removably received within the positioning hole and the assembling hole respectively to assemble the housing, the key body and the circuit board together.

10. The electronic device as claimed in claim 9, wherein the key body further comprises a main body, the main body comprises a fixing column protruding from a surface of main body, and the circuit board defines a through hole passing through the circuit board, the fixing column is removably received within the through hole to mount the key body to the circuit board.

11. The electronic device as claimed in claim 10, wherein the key body further comprises an operation body, and the positioning columns are located at the main body.

12. The electronic device as claimed in claim 11, wherein the housing member defines a receiving space and an opening communicating with the receiving space, the receiving space capable of receiving the key body, and the operation body is exposed from the opening.

13. The electronic device as claimed in claim 12, wherein the receiving space comprises a bottom surface and side surfaces, the positioning holes extend through the bottom surface, the side surfaces are perpendicularly connected to the bottom surface, and two side surfaces face each other, another side surface perpendicularly connecting the facing side surfaces.

14. The electronic device as claimed in claim 13, wherein the housing member comprises two first locking sections respectively protruding from opposite side surfaces, the two first locking sections face each other, and each first locking section comprises a mounting surface, wherein the main body further comprises a second locking section located at each opposite surface of the main body, and each second locking section comprises a slope, the mounting surfaces slide along the slopes to mount the first locking section to the second locking section.

15. The electronic device as claimed in claim 9, wherein each engaging section comprises a connecting piece connected to the surface of the main body, the connecting piece defines a matching hole, and the main body further comprises conducting sections located at opposite surfaces of the main body, an end of the conducting section passes through the matching hole to electrically connect to the circuit board.

16. The electronic device as claimed in claim 15, wherein each engaging section further comprises a fixing piece, each fixing piece is connected to the distal end of a corresponding connecting piece, and each fixing piece is removably received within the corresponding assembling hole.

17. The electronic device as claimed in claim 9, wherein the key body further comprises a frame body covering the main body, the frame body comprises a clasp portion, the clasp portion defines two notches located at opposite ends of the clasp portion, and the positioning blocks are releasably received within and exposed from the notches.

18. The electronic device as claimed in claim 17, wherein the frame body further comprises at least one latching portion connected to the clasp portion, the main body further comprises at least one hinging block protruding from opposite surfaces of the main body, and the latching portions are capable of clasping the hinging blocks to cooperatively mount the frame body to the main body.
